(19) United States
(12) Patent Application Publication
(10) Pub. No.: US 2006/0104017 A1
(43) Pub. Date: May 18, 2006

(54) Docking station for notebook computers

(76) Inventors: Vam Chang, Taipei (TW); Yi-Hsin Hsieh, Taipei (TW)

Correspondence Address: HARNESS, DICKEY & PIERCE, P.L.C., P.O. BOX 8910, RESTON, VA, 20195, US

(21) Appl. No.: 10/987,000

(22) Filed: Nov. 15, 2004

(51) Int. Cl. H05K 7/00; H05K 5/00

(52) U.S. Cl. 361/683

(57) ABSTRACT

A docking station for notebook computers includes a connection module, a detection module, a connection port and a signal-processing module. When coupling of a notebook computer and the docking station is detected, an activation signal is generated to activate the signal-processing module to process video/audio signals input to the docking station. The processed video/audio signals are output to the notebook computer to enable users to enjoy video/audio programs on the hardware facilities of the notebook computer thereby to expand the function of the docking station.

### FIELD OF THE INVENTION

The present invention relates to a docking station and particularly to a docking station for notebook computers equipped with a video/audio processing function.

### BACKGROUND OF THE INVENTION

Under the prevailing design trend that demands lean and light, the size of notebook computers shrinks constantly. However, some mechanisms and elements have size limitations to keep the notebook computer functional. In order to shrink the size of the notebook computer and maintain the function same as the desktop computer, a docking station has been developed that includes connection ports conforming to a plurality of interface specifications, such as a Universal Serial Bus (USB), a PS/2 port, IEEE1394, a parallel port, a serial port, an Ethernet port (RJ-45) and optical disk, and the like. By separating the design of the docking station and the notebook computer, the weight and size of the notebook computer may be greatly reduced. When there is a need to connect to peripheral devices, mount the notebook computer on the docking station, the peripheral devices may be connected to perform data transmission or the notebook computer may be charged. Although the docking station can provide connection with other peripheral devices, it lacks a connection function with the media (such as TV or video/audio players). Moreover, during the charging process, the notebook computer has to be mounted on the docking station, and other hardware facilities cannot be used. Hence to enhance the connecting function between the docking station and the media is an issue remained to be resolved.

### SUMMARY OF THE INVENTION

In view of the aforesaid disadvantages and problems, the primary object of the present invention is to provide a docking station for notebook computers that can couple with a notebook computer to enable users to watch TV programs on the liquid crystal screen of the notebook computer, or to receive external video/audio signals and display video pictures on the liquid crystal screen and output sound through speakers to increase the function of the docking station.

In order to achieve the foregoing object, the docking station for notebook computers according to the invention includes a connection module, a detection module, a connection port and a signal processing module.

The connection module provides a connection interface to connect to a notebook computer.

The detection module is linked to the connection module to detect the connecting condition between the notebook computer and the docking station.

The connection port includes a plurality of video/audio connection interfaces (such as a digital optical fiber input terminal, an audio/video AV input terminal, an audio/super-video input terminal, and the like) to receive external video/audio signals.

The signal-processing module is connected to the connection module to receive and process the video/audio signals, and output the processed video/audio signals to the notebook computer. It further can receive an activation signal generated by the detection module to start processing the video/audio signals.

The docking station for notebook computers according to the invention further includes a switch module, which has a plurality of switches to switch the video/audio signals output to the notebook computer to enable users to select different video/audio signal sources to watch desired programs.

By means of the docking station of the invention, the notebook computer may be coupled with the docking station so that while the charging process is proceeding, the hardware facilities of the notebook computer still can be used to watch or hear video and audio programs, thereby expanding the function of the docking station.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a system block diagram of the invention; and

FIG. 2 is an exploded view of the invention.

### DESCRIPTION OF THE PREFERRED EMBODIMENTS

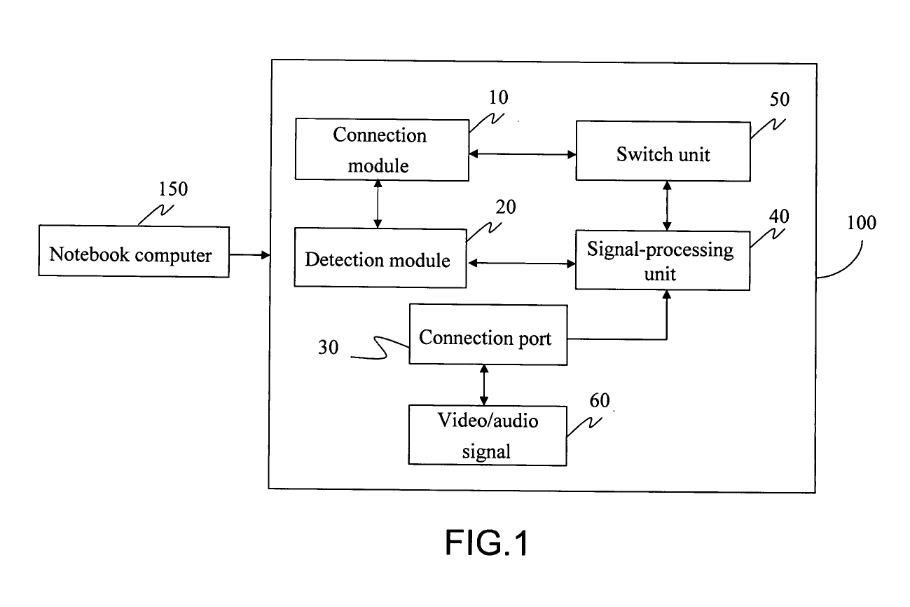

Refer to FIG. 1 for the system block diagram of the invention. The docking station 100 includes a connection module 10, a detection module 20, a connection port 30, a signal-processing module 40 and a switch module 50.

The connection module 10 provides a connection interface to connect the docking station 100 with a notebook computer 150 and serves as a signal and data transmission channel.

The detection module 20 is linked to the connection module 10 to detect the connecting condition between the notebook computer 150 and the docking station 100, and generate an activation signal after having detected that the notebook computer 150 has been connected to the docking station 100 to actuate the signal-processing module 40 to perform video/audio processes.

The connection port 30 includes a plurality of video/audio connection interfaces (such as a digital optical fiber input terminal, audio/video AV input terminal, audio/super-video input terminal, and the like) to receive external video/audio signals 60, and send the video/audio signals 60 to the signal-processing module 40 for processing.

The signal-processing module 40 is connected to the detection module 20, connection port 30 and switch module 50, to start processing the video/audio signals 60 after having received the activation signal. The signal-processing module 40 includes a tuner and a demodulator. After the connection port 30 has received the video/audio signals 60 (such as cable TV signals, video and audio players or the like), the video/audio signals 60 are sent by the tuner (not shown in the drawings) to the demodulator (not shown in the drawings) for demodulation; then are transferred through the connection module 10 to the notebook computer 150, and output through the output devices (such as a liquid crystal screen and speakers) of the notebook computer 150 to enable users to enjoy the video and audio programs.

The switch module 50 is connected to the signal-processing module 40 and the connection module 10. It includes a plurality of switches to switch the video/audio signals output to the notebook computer 150. While a user is operating on the notebook computer 150 on the docking station 100 (such as recording an optical disk through a burner or downloading files), the signal output may be switched to the liquid crystal screen through the switch module 50 to enable the user to select and watch video/audio programs, or use the notebook computer 150. And multiple switch selections may be provided according to the signal number of the video/audio signals 60, so that the user can choose to see and hear different video/audio programs desired.

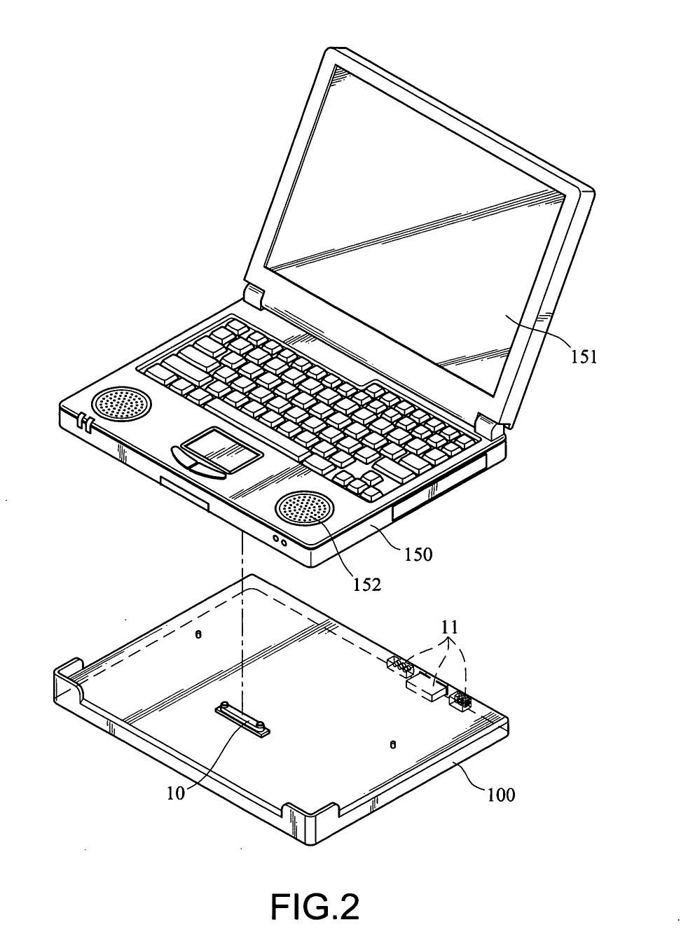

Refer to FIG. 2 for an exploded view of the invention in use that includes the docking station 100 and the notebook computer 150.

The docking station 100 has a connection port 11 on one side to receive the video/audio signals 60. The video/audio signals 60 are sent to the signal-processing module 40 for processing. The processed video/audio signals are sent to the liquid crystal screen 151 and the speaker 152 of the notebook computer 150 through the connection module 10 to be output and enjoyed by users.

Thus while the notebook computer 150 is charging, the user can still watch and hear the video/audio programs on the hardware facilities such as the liquid crystal screen 151 and the speakers 152. Therefore the function of the docking station 100 may be expanded.

By means of the docking station of the invention, users can mount the notebook computer on the docking station to watch and hear video/audio programs. Besides providing the original operation of the notebook computer, through signal switch, users can choose to watch and hear video/audio programs. Thus the function of the docking station is expanded.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

1. A docking station for a notebook computer, comprising:
a connection module connecting to the notebook computer to provide a data transmission channel;
a detection module linking to the connection module to detect connecting conditions between the notebook computer and the docking station;
a connection port linking to the connection module and including at least one video connection interface and one audio connection interface to input a video/audio signal; and
a signal-processing module linking to the connection module to process the video/audio signal, and output the processed video/audio signal; and
a switch module connected to the signal-processing module and the connection module to switch the video signal, or the audio signal, or both output to the notebook computer;
wherein the detection module generates an activation signal after having detected the notebook computer has been connected to the docking station, the signal-processing module receiving the activation signal to activate the process of the video/audio signal.

2. The docking station of claim 1, wherein the signal-processing module includes a tuner and a demodulator to execute the process of the video/audio signal.

3. (canceled)

4. The docking station of claim 1, wherein the connection port is a digital optical fiber input terminal.

5. The docking station of claim 1, wherein the connection port is a video/audio input terminal.

6. The docking station of claim 1, wherein the connection port is an audio/super-video input terminal.
